(19) United States
(12) Patent Application Publication
(10) Pub. No.: US 2012/0070933 A1
(43) Pub. Date: Mar. 22, 2012

(54) METHOD FOR MANUFACTURING DYE-SENSITIZED SOLAR CELL

(75) Inventors: Gang-Beom Kim, Cheonan (KR); Hyun-Seung Cho, Daegu (KR); Chang-Ho Jin, Cheonan (KR)

(73) Assignee: TG ENERGY INC., Cheonan (KR)

(21) Appl. No.: 13/305,661

(22) Filed: Nov. 28, 2011

Related U.S. Application Data
(63) Continuation of application No. PCT/KR2009/007005, filed on Nov. 26, 2009.

(30) Foreign Application Priority Data
May 29, 2009 (KR) 10-2009-47467

(51) Int. Cl. H01L 31/18; H01L 31/0203

(52) U.S. Cl. 438/64; 136/259; 257/E31.11

(57) ABSTRACT

The present invention provides an intermediate structure for use in manufacturing a dye-sensitized solar cell (DSSC) and a method for manufacturing a DSSC with the intermediate structure. The intermediate structure comprises a first electrode coated with a nano-particle oxide and a second electrode laminated with the first electrode by a layer formed of a sealant. The sealant layer has openings in predetermined positions such that at least a portion of the internal space formed by the first electrode, the second electrode, and the sealant layer can communicate with the outside. With the intermediate structure, a superior quality of a DSSC can be manufactured in a simpler and more cost-effective way.

### CROSS-REFERENCES TO RELATED APPLICATION

This is a continuation of International Application No. PCT/KR2009/007005, with an international filing date of Nov. 26, 2009, which claims the benefit of Korean Application No. 10-2009-47467 filed on May 29, 2009, the entire contents of which applications are incorporated herein by reference.

### BACKGROUND OF THE DISCLOSURE

1. Technical Field

The present invention relates to an intermediate structure for use in manufacturing a dye-sensitized solar cell (DSSC) and a method of manufacturing a DSSC using the same.

2. Related Art

The exhaustion of fossil fuel, a sudden rise in price of fossil fuel, and a rapid change in the climate of the earth require sustainable energy acquisition technologies. From among the technologies, solar energy has been in the spotlight in terms of unlimited cleanness and stability.

A silicon solar cell has been widely researched and used industrially, but it is said to be economically infeasible because it is expensive. As an alternative, a DSSC has been proposed as it is not expensive and it has energy conversion efficiency comparable to that of the silicon solar cell.

In general, a DSSC includes a semiconductor electrode (hereinafter referred to as a ‘transparent electrode’), a catalytic electrode (hereinafter referred to as a ‘counter electrode’), and an electrolyte sandwiched between the transparent electrode and the counter electrode. The transparent electrode is a transparent conductive substrate coated with nano-particle oxides covalently bonded with photosensitive dye molecules. The counter electrode is a transparent conductive substrate coated with platinum or carbon. The dye molecules function to generate electron-hole pairs by absorbing solar light.

Typically, such a DSSC is fabricated as follows. Nano-particle oxides are coated on a transparent electrode substrate, sintered, and then dipped in a photosensitive dye solution so that the dye molecules contained in the dye solution are absorbed to the coated nano-particle oxides. Holes 16 for injecting an electrolyte are processed in the transparent electrode or the counter electrode. After the two electrodes are laminated and adhered, the electrolyte is injected through the holes 16, and the holes 16 are then closed by hole finishing materials 17. FIG. 1 is a vertical cross-sectional view of the DSSC fabricated by the above-described conventional method.

The conventional method, however, requires a separate step for processing the holes 16, which causes the production cost to be increased. In addition, the hole finishing materials cause the thickness of the solar cell produced by the conventional method has to be increased and the surface of the electrode to be non-uniform, as shown in FIG. 1.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

Accordingly, an object of the present invention is to provide a method of manufacturing a DSSC in a simpler and more cost-effective way. Another object is to provide an intermediate structure for use in manufacturing a DSSC in a simpler and more cost-effective way.

In one aspect, the present invention provides an intermediate structure for use in manufacturing a DSSC. The intermediate structure comprises: a first electrode coated with a nano-particle oxide, and a second electrode laminated with the first electrode by a layer formed of a sealant, wherein the sealant layer has openings in predetermined positions such that at least a portion of the internal space formed by the first electrode, the second electrode, and the sealant layer can communicate with the outside.

In another aspect, the present invention provides a method for manufacturing a DSSC. According to an embodiment, the method comprises the steps of: fabricating a counter electrode; fabricating a pre-transparent electrode by coating a nano-particle oxide on a transparent conductive substrate and then sintering the nano-particle oxide; laminating and adhering the pre-transparent electrode and the counter electrode by a layer formed of a sealant, wherein the sealant layer has openings in predetermined positions such that at least a portion of the internal space defined by the pre-transparent electrode, the counter electrode, and the sealant layer communicates with the outside; adsorbing photosensitive dye molecules on the nano-particle oxide by injecting a photosensitive dye molecule solution through the openings; and injecting an electrolyte through the openings and then closing the openings.

According to another embodiment, the method comprises the steps of: fabricating a counter electrode; fabricating a pre-transparent electrode by coating a nano-particle oxide on a transparent conductive substrate and sintering the nano-particle oxide; adsorbing photosensitive dye molecules on the sintered nano-particle oxide to prepare a transparent electrode; laminating and adhering the transparent electrode and the counter electrode by a layer formed of a sealant, wherein the sealant layer has openings in predetermined positions such that at least a portion of the internal space defined by the transparent electrode, the counter electrode, and the sealant layer communicates with the outside; and injecting an electrolyte through the openings and then closing the openings.

As described above, according to the present invention, there can be provided the method of manufacturing a DSSC having a new structure, which has an advantage in that a process of manufacturing a solar cell can be shortened and the production cost can be reduced because holes for injecting an electrolyte needs not to be processed and the percent defective due to hole processing can be reduced. The DSSCs manufactured by the method according to the present invention have a uniform thickness and an even surface because there is no need to perform a step of closing the holes by finishing hole materials.

The above and other features and advantageous effects are discussed in detail below.

### BRIEF DESCRIPTION OF THE DRAWINGS

FIG. 1 is a vertical cross-sectional view of a conventional DSSC.

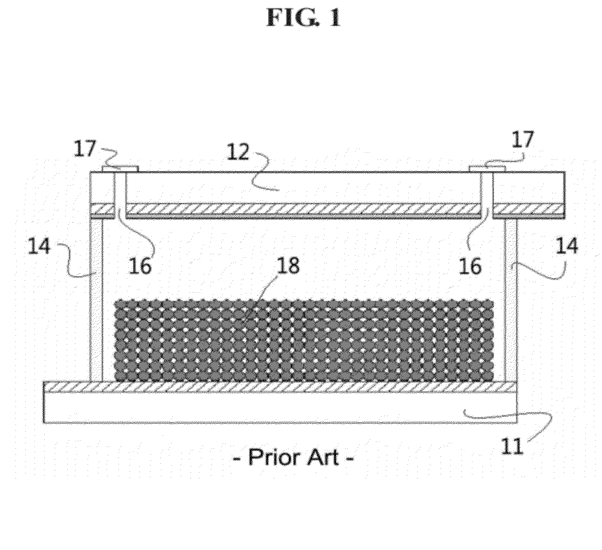

FIGS. 2A and 2B are vertical and horizontal cross-sectional views of a DSSC intermediate according to an embodiment of the present invention, respectively.

FIG. 3 is a perspective view of a DSSC intermediate having a metal grid formed in the conductive substrate of the DSSC according to an embodiment of the present invention.

FIG. 4 is a diagram showing an apparatus for injecting dye molecules into openings formed in DSSC intermediates according to an embodiment of the present invention.

### DETAILED DESCRIPTION OF EMBODIMENTS

The present invention is described in detail with reference to the accompanying drawings. The drawings and the description, however, are only illustrative in order to easily describe the contents and scope of the technical spirit of the present invention, but the technical scope of the present invention is not limited or changed by the drawings and the description. Furthermore, it would be evident to a person having ordinary skill in the art that a variety of modifications and changes are possible within the scope of the technical spirit of the present invention on the basis of the illustration.

As discussed above, in one aspect, the present invention provides an intermediate structure to be used in manufacturing a DSSC. The components of a DSSC and the structures of the components are not limited to particular ones and can be selected appropriately by those skill in the art, detailed description of which is thus omitted.

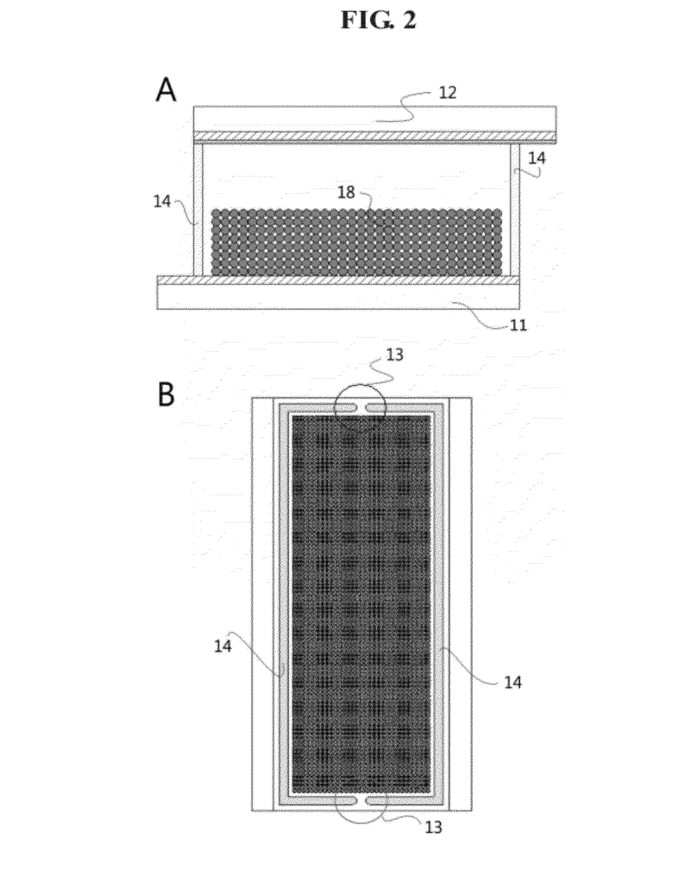

FIGS. 2A and 2B are vertical and horizontal cross-sectional views of a DSSC intermediate according to an embodiment of the present invention, respectively. The DSSC intermediate comprises a transparent electrode 11 coated with a nano-particle oxide, a counter electrode 12 laminated with the transparent electrode 11 by a layer 14 formed of a sealant. The sealant layer 14 has openings 13 in predetermined positions such that at least a portion of the internal space formed by the two electrodes 11, 12 and the sealant layer 14 communicates with the outside. Through the openings 13, a dye solution or an electrolyte can be injected. The DSSC intermediates according to the present invention enable the thickness of the solar cells resulting from the intermediates to be uniform and the surface of the electrodes therefrom to be even (smooth).

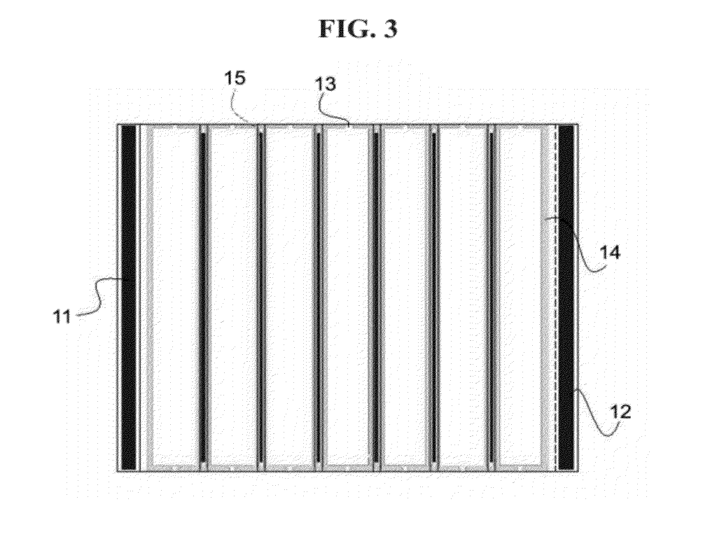

Further, in various embodiments, the DSSC intermediate may be used to manufacture a lattice type (or grid type) DSSC having a serial or parallel structure in which a metal grid 15 is formed on the transparent conductive substrate or a metal grid 15 is formed on the substrate and a thin transparent conductive film is coated thereon (FIG. 3) in order to lower electrical resistance of the transparent conductive substrate. Preferably, the openings 13 may be formed at both ends of each of grid patterns. The structure of the lattice or grid type DSSC is not limited to a particular one and can be selected by those skilled in the art, detailed description of which is thus omitted.

As the sealant 14, any material that can adhere the electrodes can be used. Examples of the sealant 14 may include, but not limited to, a thermoplastic resin film, a thermosetting resin, a photo-curable resin, and a glass composition. Those skilled in the art can select an appropriate sealant material. For example, in some cases, a lead-free glass composition can be selected because a glass composition containing lead can negatively affect the characteristics of the electrodes in a heat treatment process. In another aspect, the present invention provides a method for manufacturing a DSSC using the intermediate structure. The method may comprise the steps of fabricating a transparent electrode coated with a nano-particle oxide, fabricating a counter electrode, fabricating an intermediate structure having openings formed therein, injecting an electrolyte, and closing the openings of the intermediate structure. The method may further comprise a step of adsorbing dye molecules on the nano-particle oxide. The adsorption step can be performed before or after the step of fabricating the intermediate structure.

### Embodiment 1

### Dye Adsorption Before Intermediate Structure Fabrication

Two electrodes are fabricated by a method available to those skilled in the art. For instance, a pre-transparent electrode is fabricated by coating a nano-particle oxide 18 on a transparent conductive substrate and sintering the nano-particle oxide and a counter electrode is fabricated by coating platinum or carbon on a transparent conductive substrate. The term ‘pre-transparent electrode’ used herein refers to a transparent electrode coated with a nano-prarticle oxide before photosensitive dye molecules are adsorbed on the coated nano-particle oxide.

Photosensitive dye molecules are adsorbed on the sintered nano-particle oxide by using a dye adsorption method available to those skilled in the art (e.g., by dipping the pre-transparent electrode into a dye molecule solution). An intermediate structure is then fabricated by laminating the two electrodes by a sealant layer having openings in predetermined positions. Preferably, the intermediate structure can be fabricated by using, e.g., laser processing or hot pressing. Thereafter, an electrolyte is injected through the openings and the openings are then closed using polymer resin (e.g. thermoplastic resin, thermosetting resin, photo-curable resin) or glass frit by laser processing or thermal treatment.

### Embodiment 2

### Dye Adsorption After Intermediate Structure Fabrication

Two electrodes are fabricated by a method available to those skilled in the art. For instance, a pre-transparent electrode is fabricated by coating a nano-particle oxide on a transparent conductive substrate and sintering the nano-particle oxide and a counter electrode is fabricated by coating platinum or carbon on a transparent conductive substrate. The term ‘pre-transparent electrode’ used herein refers to a transparent electrode coated with a nano-prarticle oxide before photosensitive dye molecules are adsorbed on the coated nano-particle oxide.

An intermediate structure is fabricated by laminating the two electrodes by a sealant layer having openings in predetermined positions. Preferably, the intermediate structure can be fabricated by using, e.g., laser processing or hot pressing. Photosensitive dye molecules are then adsorbed on the sintered nano-particle oxide by introducing a photosensitive dye molecule solution into the openings of the intermediate.

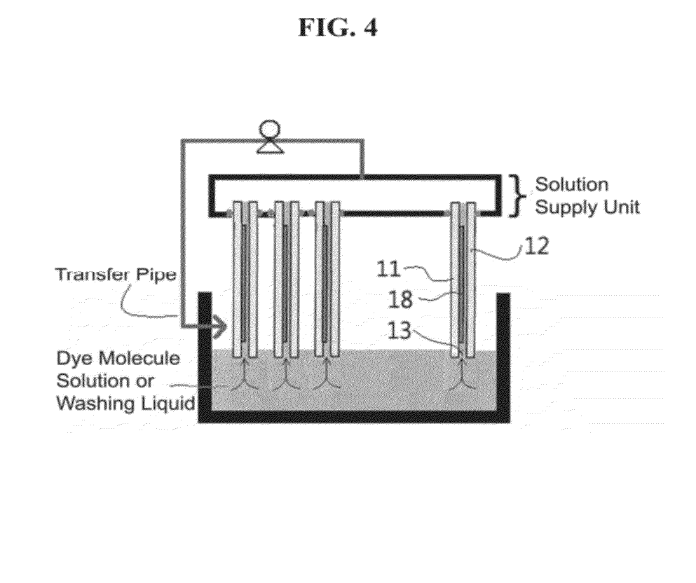

Preferably, the step of introducing a photosensitive dye molecule solution into the openings may include the steps of (i) allowing a photosensitive dye molecule solution to flow into the internal space defined by the two electrodes and the sealant layer through the openings thereby adsorbing dye molecules on the sintered nano-particle oxide; and (ii) after the dye molecules are adsorbed, allowing washing liquid to flow into the internal space through the openings, thereby removing residual (non-adsorbed) dye molecules. FIG. 4 is a diagram showing an exemplary apparatus that can be used to adsorb the dye molecules, as described in Korean Patent Application No. 10-2009-21406, which is incorporated herein by reference in its entirety. Although FIG. 4 shows that the dye molecule solution flows upwardly, it can be designed to flow downwardly or horizontally using, e.g., a pump or a vacuum decompression method. As shown in FIG. 4, to prevent the waste of the dye molecule solution and improve working efficiency, it may be preferable to circulate the photosensitive dye molecule solution. It may also be preferable to repeatedly circulate the photosensitive dye molecule solution, in which case the concentration of the dye molecules may, if necessary, be controlled to be a predetermined value. Meanwhile, in removing the residual (non-adsorbed) dye molecules, in a modified embodiment, the washing liquid may be evaporated by circulating hot dry air around the internal space via the openings, thereby being able to rapidly remove the washing liquid. Thereafter, an electrolyte is injected through the openings by the same method used in introducing the dye molecule solution and the openings are then closed using polymer resin or glass frit by laser processing or thermal treatment.

The present invention provides advantageous effects. For example, a DSSC can be manufactured in a simpler and more cost-effective way. In detail, since the photosensitive dye molecules are adsorbed after the counter electrode and the pre-transparent electrode are sealed by the sealant, thermal processing steps taken before the dye molecules are adsorbed has no influence on the performance of the solar cell, which makes it possible for a person having ordinary skill in the art to adequately and conveniently design the thermal processing or laser processing step until the intermediate structure is fabricated. Also, the quality of the produced DSSC can be improved: e.g., the thickness of the produced DSSCs are uniform and the surface of the electrodes is even; the dye molecules of the DSSCs are not decomposed.

What is claimed is:

1. A method of manufacturing a dye-sensitized solar cell, comprising the steps of:
fabricating a counter electrode;
fabricating a pre-transparent electrode by coating a nano-particle oxide on a transparent conductive substrate and then sintering the nano-particle oxide;
laminating and adhering the pre-transparent electrode and the counter electrode by a layer formed of a sealant, wherein the sealant layer has openings in predetermined positions such that at least a portion of the internal space defined by the pre-transparent electrode, the counter electrode, and the sealant layer communicates with the outside;
adsorbing photosensitive dye molecules on the nano-particle oxide by injecting a photosensitive dye molecule solution through the openings; and
injecting an electrolyte through the openings and then closing the openings.

2. The method according to claim 1, wherein the sealant is one selected from a group consisting of a thermoplastic resin, a thermosetting resin, a photo-curable resin, and a glass composition.

3. The method according to claim 1, wherein a metal grid is formed in the transparent conductive substrate, and the openings are formed at both ends of each of grid patterns.

4. The method according to claim 3, wherein the sealant is one selected from a group consisting of a thermoplastic resin, a thermosetting resin, a photo-curable resin, and a glass composition.

5. A method of manufacturing a dye-sensitized solar cell, comprising the steps of:
fabricating a counter electrode;
fabricating a pre-transparent electrode by coating a nano-particle oxide on a transparent conductive substrate and sintering the nano-particle oxide;
adsorbing photosensitive dye molecules on the sintered nano-particle oxide to prepare a transparent electrode;
laminating and adhering the transparent electrode and the counter electrode by a layer formed of a sealant, wherein the sealant layer has openings in predetermined positions such that at least a portion of the internal space defined by the transparent electrode, the counter electrode, and the sealant layer communicates with the outside; and
injecting an electrolyte through the openings and then closing the openings.

6. The method according to claim 5, wherein the sealant is one selected from a group consisting of a thermoplastic resin, a thermosetting resin, a photo-curable resin, and a glass composition.

7. The method according to claim 5, wherein a metal grid is formed in the transparent conductive substrate, and the openings are formed at both ends of each of grid patterns.

8. The method according to claim 7, wherein the sealant is one selected from a group consisting of a thermoplastic resin, a thermosetting resin, a photo-curable resin, and a glass composition.

9. An intermediate structure for use in manufacturing a dye-sensitized solar cell, the intermediate structure comprising:
a first electrode coated with a nano-particle oxide, and
a second electrode laminated with the first electrode by a layer formed of a sealant,
wherein the sealant layer has openings in predetermined positions such that at least a portion of the internal space formed by the first electrode, the second electrode, and the sealant layer can communicate with the outside.

10. The intermediate structure according to claim 9, wherein the sealant is one selected from a group consisting of a thermoplastic resin, a thermosetting resin, a photo-curable resin, and a glass composition.

11. The intermediate structure according to claim 9, wherein the nano-particle oxide of the first electrode is adsorbed by photosensitive dye molecules.

12. The intermediate structure according to claim 11, wherein the sealant is one selected from a group consisting of a thermoplastic resin, a thermosetting resin, a photo-curable resin, and a glass composition.
